(19) United States
(12) Patent Application Publication
(10) Pub. No.: US 2025/0318237 A1
(43) Pub. Date: Oct. 9, 2025

(54) SELF ALIGNED BACKSIDE CONTACTS COMPATIBLE WITH PASSIVE DEVICES

(71) Applicant: INTERNATIONAL BUSINESS MACHINES CORPORATION, ARMONK, NY (US)

(72) Inventors: Xiaoming Yang, Clifton Park, NY (US); Ruilong Xie, Niskayuna, NY (US); Takashi Ando, Eastchester, NY (US); Kisik Choi, Watervliet, NY (US)

(21) Appl. No.: 18/628,856

(22) Filed: Apr. 8, 2024

(51) Int. Cl. H01L 29/417; H01L 23/528; H01L 27/092; H01L 29/06; H01L 29/423; H01L 29/775; H01L 29/786

(52) U.S. Cl. CPC H10D 64/254; H01L 23/5286; H10D 30/43; H10D 30/6735; H10D 30/6757; H10D 62/121; H10D 84/85

(57) ABSTRACT

A nanosheet semiconductor structure including a logic device region comprising logic devices having backside contact structures embedded in a backside dielectric layer, and a passive device region including passive devices on a continuous silicon substrate, where a height of the backside dielectric layer in the logic device region is substantially equal to a height of the continuous silicon substrate in the passive device region.

### BACKGROUND

The present invention generally relates to semiconductor structures, and more particularly to nanosheet transistor structures having self-aligned backside contacts compatible with passive devices.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a logic device region including logic devices having backside contact structures embedded in a backside dielectric layer, and a passive device region including passive devices on a continuous silicon substrate, where a height of the backside dielectric layer in the logic device region is substantially equal to a height of the continuous silicon substrate in the passive device region.

According to another embodiment of the present invention, a semiconductor structure is provided. The semiconductor structure may include a logic device region including logic devices having backside contact structures embedded in a first backside dielectric layer, a passive device region including passive devices on a continuous silicon substrate, and a second backside dielectric layer below the first backside dielectric layer in the logic device region and below the continuous silicon substrate in the passive device region, where a topmost surface of the second backside dielectric layer is above a bottommost surface of the first backside dielectric layer.

According to another embodiment of the present invention, a semiconductor structure is provided. The semiconductor structure may include a logic device region including logic devices having backside contact structures embedded in a first backside dielectric layer, a passive device region including passive devices on a continuous silicon substrate, and a dielectric etch stop layer physically separating the first backside dielectric layer from a second backside dielectric layer.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2, 3, 4, and 5 are cross-sectional views of the semiconductor structure during an intermediate step of a method of fabricating nanosheet transistor structures according to an exemplary embodiment;

FIGS. 6, 7, 8, and 9 are cross-sectional views of the semiconductor structure after flipping the assembly and recessing the substrate according to an exemplary embodiment;

FIGS. 10, 11, 12, and 13 are cross-sectional views of the semiconductor structure after forming a first mask and removing portions of the etch stop layer according to an exemplary embodiment;

FIGS. 14, 15, 16, and 17 are cross-sectional views of the semiconductor structure after removing exposed portions of the top semiconductor layer according to an exemplary embodiment;

FIGS. 18, 19, 20, and 21 are cross-sectional views of the semiconductor structure after forming first backside dielectric layer according to an exemplary embodiment;

FIGS. 22, 23, 24, and 25 are cross-sectional views of the semiconductor structure after forming a second mask and removing portions of the first backside dielectric layer to form backside contact trenches according to an exemplary embodiment;

FIGS. 26, 27, 28, and 29 are cross-sectional views of the semiconductor structure removing the placeholders and forming backside contact structures according to an exemplary embodiment;

FIGS. 30, 31, 32, and 33 are cross-sectional views of the semiconductor structure recessing the backside contact structures according to an exemplary embodiment;

FIGS. 34, 35, 36, and 37 are cross-sectional views of the semiconductor structure forming a dielectric etch stop liner and a second backside dielectric layer according to an exemplary embodiment;

FIGS. 38, 39, 40, and 41 are cross-sectional views of the semiconductor structure removing portions of the second backside dielectric layer to form backside via trenches according to an exemplary embodiment; and

FIGS. 42, 43, 44, and 45 are cross-sectional views of the semiconductor structure forming backside via structures and backside wiring layers according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

As semiconductor devices continue to decrease in size, it has become desirable to provide distances between the near-most nFET and pFET active regions (i.e., the “N2P space”) on the order of about 8 nanometers (nm) to about 30 nm. Providing N2P spaces at these dimensions can present challenges to communicating with the pFET section and the nFET section. Specifically, N2P spaces on this order reduce the process window within which contact structures connecting the nFET section and pFET section could electrically short with one another. Although the process window can be broadened by positioning the contact structures at locations laterally offset from the N2P space, doing so increases the electrical resistance between the contact structures and the respective pFET section and nFET section, thereby offsetting any improvement in process window and/or electrical characteristics of the multilayer IC device.

Complementary field effect transistors, including gate-all-around transistor devices and nanosheet transistor devices, have known advantages over conventional transistor structures in terms of density, performance, power consumption, and integration. However, fabricating device contacts on a backside of the wafer presents unique challenges. More specifically, conventional backside contact and placeholder fabrication techniques are incompatible with fabrication of neighboring passive devices. For example, self-aligned backside source drain contacts at relatively small N2P spacing are often initially formed as a merged contact structure and subsequently polished down to the isolation regions to provide individual self-aligned backside contacts. In doing so, the bulk silicon substrate in the passive device regions is also polished and removed despite the need to maintain the continuity of the silicon substrate beneath and below devices in the passive regions of the structure.

The present invention generally relates to semiconductor structures, and more particularly to nanosheet transistor structures having self-aligned backside contacts compatible with passive devices. More specifically, the nanosheet transistor structures and associated method disclosed herein enable a novel solution for providing nanosheet transistor structures having self-aligned backside contacts compatible with passive devices. For example, the nanosheet transistor structures and associated method disclosed herein provide a unique approach to producing individual backside source drain contacts for logic devices while maintaining silicon substrate continuity beneath and below passive devices.

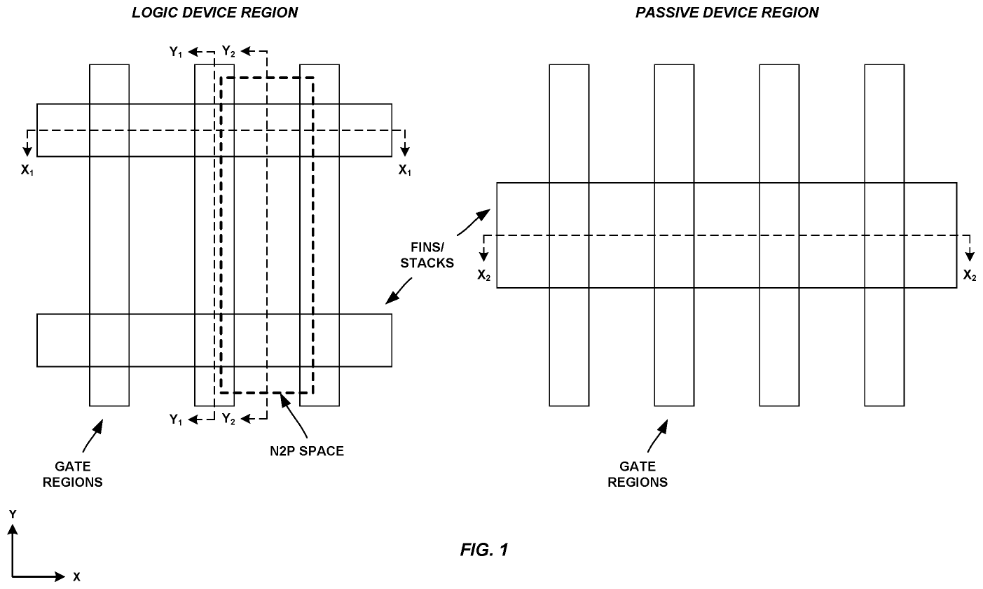

Exemplary embodiments of nanosheet transistor structures having self-aligned backside contacts compatible with passive devices are described in detail below by referring to the accompanying drawings in FIGS. 1 to 45. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The two views of the generic structure illustrated in FIG. 1 shows multiple fins/stacks and multiple gate regions situated perpendicular to one another. One of the views represents a logic device region of the generic structure and the other views represents a passive device region of the generic structure. FIGS. 1-45 represent cross section views oriented as indicated in FIG. 1

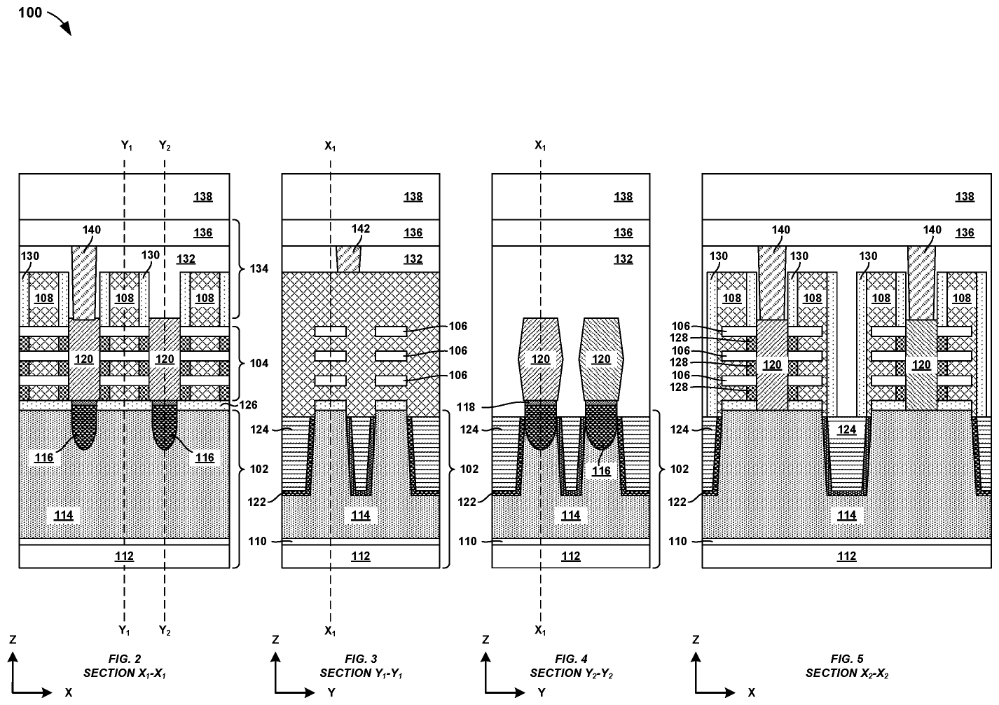

Referring now to FIGS. 2, 3, 4, and 5, a structure 100 is shown during an intermediate step of a method of fabricating a nanosheet transistor structure according to an embodiment of the invention. FIG. 2 depicts a cross-sectional view of the structure 100 taken along line X₁-X₁, FIG. 3 depicts a cross-sectional view of the structure 100 taken along line Y₁-Y₁, FIG. 4 depicts a cross-sectional view of the structure 100 taken along line Y₂-Y₂, and FIG. 5 depicts a cross-sectional view of the structure 100 taken along line X₂-X₂.

The structure 100 illustrated in FIGS. 2-5 includes an array of nanosheet transistors formed on a substrate 102 in accordance with known techniques. As illustrated, the array of nanosheet transistors includes nanosheet stacks 104. Each nanosheet stack 104 includes a plurality of silicon channels 106 surrounded by a single gate 108. For purposes of orientation, the substrate 102 is herein referred to as being on a “backside” of the structure 100 and the array of nanosheet transistors are herein referred to as being on a “frontside” of the structure 100. Further, certain features may be described herein as having a relative position with respect to the frontside or backside of the structure 100.

The substrate 102 may be a layered semiconductor such as a silicon-on-insulator or SiGe-on-insulator, where an etch stop layer 110 separates a base substrate 112 from a top semiconductor layer 114. Unlike conventional layered semiconductor substrates, the etch stop layer 110 of the substrate 102 may include any material which affects the desired etch selectivity during subsequent processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function.

In the present embodiment, both the base substrate 112 and the top semiconductor layer 114 may be any bulk substrate made from any of several known semiconductor materials such as, for example, silicon, germanium, silicon-germanium alloy, and compound (e.g. III-V and II-VI) semiconductor materials. For example, both the base substrate 112 and the top semiconductor layer 114 may be made from silicon. Additionally, both the etch stop layer 110 and the base substrate 112 are sacrificial and will not remain in the final structure. As such, thickness of the top semiconductor layer 114, and similarly the position of the etch stop layer 110, approximately denote a relative position of subsequently formed backside features, such as, backside wiring layers or a backside power delivery network.

The structure 100 further includes placeholders 116, buffer layers 118, and source drain regions 120 generally arranged between adjacent nanosheet stacks 104, as illustrated.

The placeholders 116 are formed by filling self-aligned openings in the top semiconductor layer 114 between adjacent nanosheet stacks 104 with a sacrificial material according to known techniques. Specifically, after filling, the sacrificial material is recessed to create the placeholders 116 according to known techniques. In an embodiment, the sacrificial material is silicon germanium or amorphous silicon epitaxially grown from the surfaces of the top semiconductor layer 114. In another embodiment, the sacrificial material is SiC, SiOC deposited using, for example, chemical vapor deposition (CVD) or plasma enhanced CVD (PECVD) and subsequently recessed using, for example, reactive ion etching (RIE). Other suitable deposition and recessing techniques may be used provided they do not induce a physical or chemical change to the silicon channels 106.

The buffer layers 118 are formed on top of the placeholders 116 according to known techniques. Specifically, an etch stop material is formed directly on top of the placeholders 116. In an embodiment, the etch stop material can be any silicon-based material suitable to provide needed etch stop properties during backside processing. For example, the buffer layers 118 are designed to allow the subsequent removal of the placeholders 116 selective to the source drain regions 120.

The source drain regions 120 are formed on top of the buffer layer 118 according to known techniques. Specifically, the source drain regions 120 are disposed between adjacent nanosheet stacks 104 in direct contact with exposed ends of the silicon channels 106. More specifically, the source drain regions 120 may be epitaxially grown from the exposed ends of the silicon channels 106 according to known techniques.

According to the disclosed embodiments, one of the source drain regions 120 represented in the cross-sectional views of the structure 100 taken along line Y₂-Y₂ (e.g. FIG. 4) is associated with a pFET device and the other is associated with an nFET device. In addition, nFET devices and pFET devices of the present disclosure have very tight the N2P space, as defined above.

The structure 100 further includes shallow trench isolation regions (hereinafter “STI regions”) which extend partially into the substrate 102 below the array of nanosheet transistors. In general, the STI regions may each include an isolation liner 122 and an isolation fill 124. For example, the isolation liner 122 is SiN, SiON, or SiOCN, and the isolation fill 124 is silicon oxide (SiO) or silicon nitride (SiN).

The structure 100 further includes stack spacers 126, inner spacers 128, and gate spacers 130.

The stack spacers 126 are disposed directly beneath the nanosheet stacks 104 separating them from the substrate 102. Specifically, for example, a relatively thin layer of silicon nitride is conformally deposited prior to forming the nanosheet stacks 104. In some embodiments, for example, the stack spacers 126 may be composed of SiN, SiBCN, SiOCN, SiOC, or any other combination of low-k materials. Like the buffer layers 118, the stack spacers 126 can provide etch selectivity during backside processing.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

The inner spacers 128 are disposed between alternate channels (106), and laterally separate the gates 108 from the source drain regions 120, as illustrated. The inner spacers 128 provide necessary electrical insulation between the gates 108 and the source drain regions 120.

The gate spacers 130 are added to define the channel length and the source drain regions, and ultimately electrically insulate the gates 108 from subsequently formed structures, such as, for example, source drain contact structures. The gate spacers 130 are critical for electrically insulating the gates 108 from the source drain regions 120 or subsequently formed contact structures. In at least one embodiment, the gate spacers 130 include silicon nitride, silicon boron nitride, silicon carbon nitride, silicon boron carbon nitride, or other known equivalents.

The structure 100 further includes a dielectric layer 132 directly above and surrounding the source drain regions 120. The dielectric layer 132 is composed of any suitable interlayer dielectric material, such as, for example, oxides such as silicon oxide (SiOₓ), nitrides such as silicon nitride (SiₓN_{y}), and/or low-K materials such as SiCOH or SiBCN. In another embodiment, is composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In yet another embodiment, a self-planarizing material such as a spin-on glass (SOG) or a spin-on low-k dielectric material such as SiLK™ can be used to form the dielectric layer 132. Using a self-planarizing dielectric material as the dielectric layer 132 can avoid the need to perform a subsequent planarizing step. After formation, top surfaces of the dielectric layer 132 are typically made flush, or substantially flush, with top surfaces of the gates 108 and the gate spacers 130 by chemical mechanical polishing techniques.

The structure 100 further includes a middle-of-line 134, a back-end-of-line 136, a carrier wafer 138.

The middle-of-line 134 includes source drain contacts 140 and gate contacts 142 which may be generally referred to as middle-of-line contacts. The source drain contacts 140 and the gate contacts 142 are formed according to known techniques. The back-end-of-line 136 may include vias and metal lines which may be generally referred to as back-end-of-line interconnects. The vias and the metal lines are formed according to known techniques. Finally, the carrier wafer 138 is secured to a top of the structure 100 according to an embodiment of the invention. The carrier wafer 138 is attached, or removably secured, to the back-end-of-line 136. In general, and not depicted, the carrier wafer 138 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 138 according to known techniques.

Although only a limited number of components, devices, or structures are shown, embodiments of the present invention shall not be limited by any quantity otherwise illustrated or discussed herein.

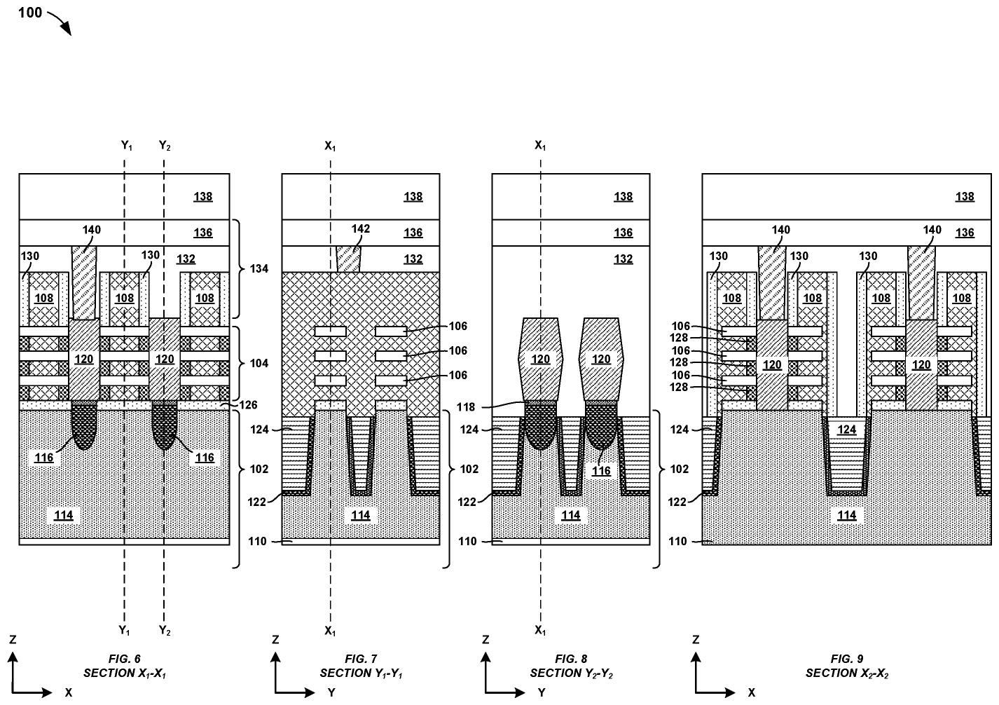

Referring now to FIGS. 6, 7, 8, and 9, the structure 100 is shown after flipping the assembly and recessing the substrate 102 according to an embodiment of the invention. FIG. 6 depicts a cross-sectional view of the structure 100 taken along line X₁-X₁, FIG. 7 depicts a cross-sectional view of the structure 100 taken along line Y₁-Y₁, FIG. 8 depicts a cross-sectional view of the structure 100 taken along line Y₂-Y₂, and FIG. 9 depicts a cross-sectional view of the structure 100 taken along line X₂-X₂.

First, the structure 100 is flipped 180 degrees to prepare for backside processing. In general, backside processing includes fabrication or processing of the structure 100 opposite the active devices and wiring layers. Next, the substrate 102 is recessed according to known techniques. Specifically, the base substrate 112 is recessed or completely removed to expose the etch stop layer 110, as shown. It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

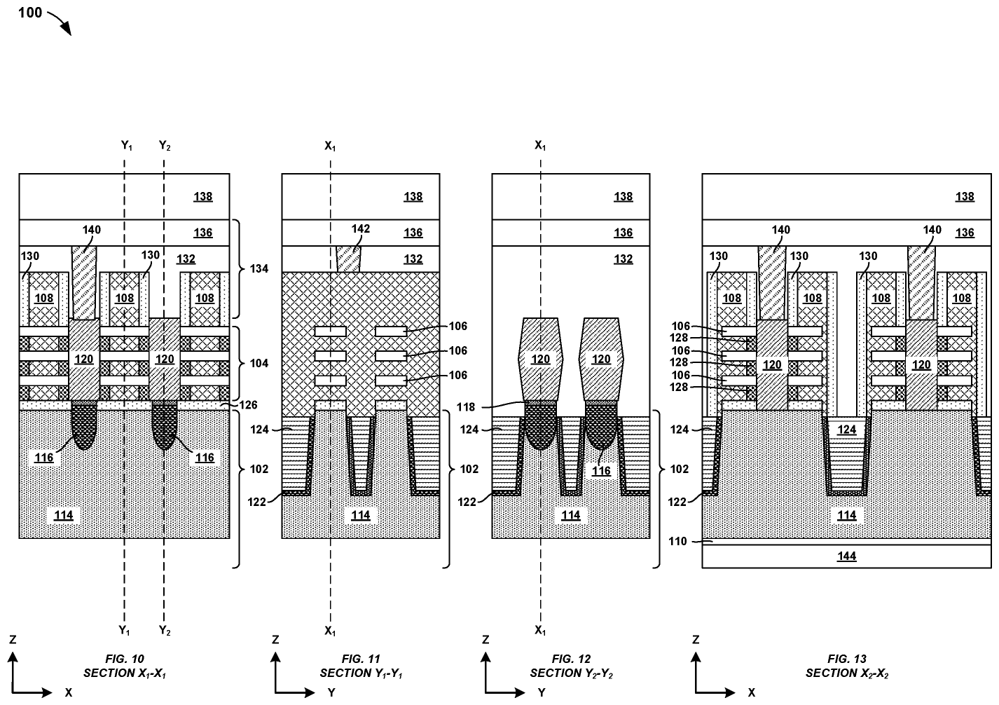

Referring now to FIGS. 10, 11, 12, and 13, the structure 100 is shown after forming a first mask 144 and removing portions of the etch stop layer 110 according to an embodiment of the invention. FIG. 10 depicts a cross-sectional view of the structure 100 taken along line X₁-X₁, FIG. 11 depicts a cross-sectional view of the structure 100 taken along line Y₁-Y₁, FIG. 12 depicts a cross-sectional view of the structure 100 taken along line Y₂-Y₂, and FIG. 13 depicts a cross-sectional view of the structure 100 taken along line X₂-X₂.

First, the first mask 144 is deposited and subsequently patterned to expose certain portions of the structure 100 according to known techniques. The first mask 144 can be an organic planarization layer (OPL) or a layer of material that is capable of being planarized or etched by known techniques. In an embodiment, for example, the first mask 144 can be an amorphous carbon layer able to withstand subsequent processing temperatures. The first mask 144 can preferably have a thickness sufficient to cover existing structures. After depositing the first mask 144, a dry etching technique is applied to pattern or recess the first mask 144 according to known techniques. Specifically, the first mask 144 is etched or removed selective to the etch stop layer 110.

According to the disclosed embodiments, the first mask 144 is patterned to expose certain regions of the structure 100 while remaining present in other regions of the structure 100. For example, after patterning the first mask 144, portions of the structure 100 in logic device regions are generally exposed and portions of the structure 100 in passive device regions remain generally protected, as illustrated. Consistent with the labels provided in FIG. 1, the first mask 144 is removed from the portions of the structure 100 in FIGS. 10, 11, and 12, but not in FIG. 13.

Next, exposed portions of the etch stop layer 110 are selectively removed according to known techniques. Specifically, the exposed portions of the etch stop layer 110 are removed selective to the top semiconductor layer 114, as illustrated. Furthermore, the exposed portions of the etch stop layer 110 are generally removed from the logic device regions and generally remain in the passive device regions.

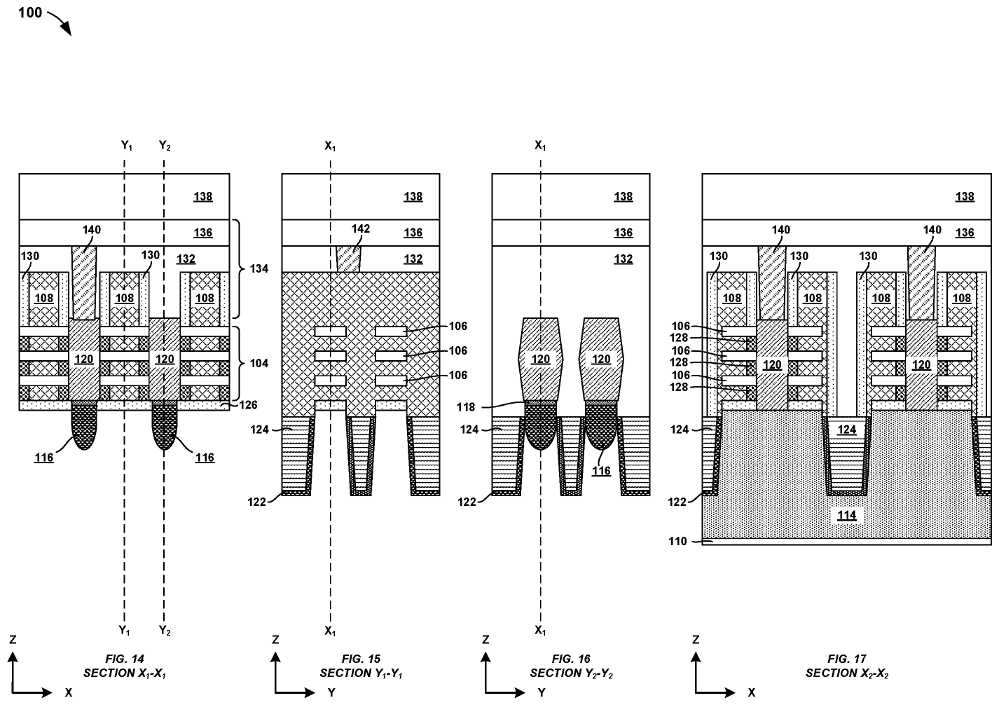

Referring now to FIGS. 14, 15, 16, and 17, the structure 100 is shown after removing exposed portions of the top semiconductor layer 114 according to an embodiment of the invention. FIG. 14 depicts a cross-sectional view of the structure 100 taken along line X₁-X₁, FIG. 15 depicts a cross-sectional view of the structure 100 taken along line Y₁-Y₁, FIG. 16 depicts a cross-sectional view of the structure 100 taken along line Y₂-Y₂, and FIG. 17 depicts a cross-sectional view of the structure 100 taken along line X₂-X₂.

First, any planarization layer, for example the first mask 144, is removed by ashing. Next, the top semiconductor layer 114 is recessed and removed according to known techniques. Specifically, the top semiconductor layer 114 is removed selective to the placeholders 116, the stack spacers 126, the gates 108, and the STI regions, as illustrated. Some erosion of the placeholders 116 is anticipated to be an unintended consequence resulting from selectively removing the top semiconductor layer 114; however, such erosion of the placeholders 116 is immaterial to the present disclosure and therefore not specifically illustrated in the figures. It is further noted that the top semiconductor layer 114 remains in the passive device region due to the presence of the etch stop layer 110, as illustrated.

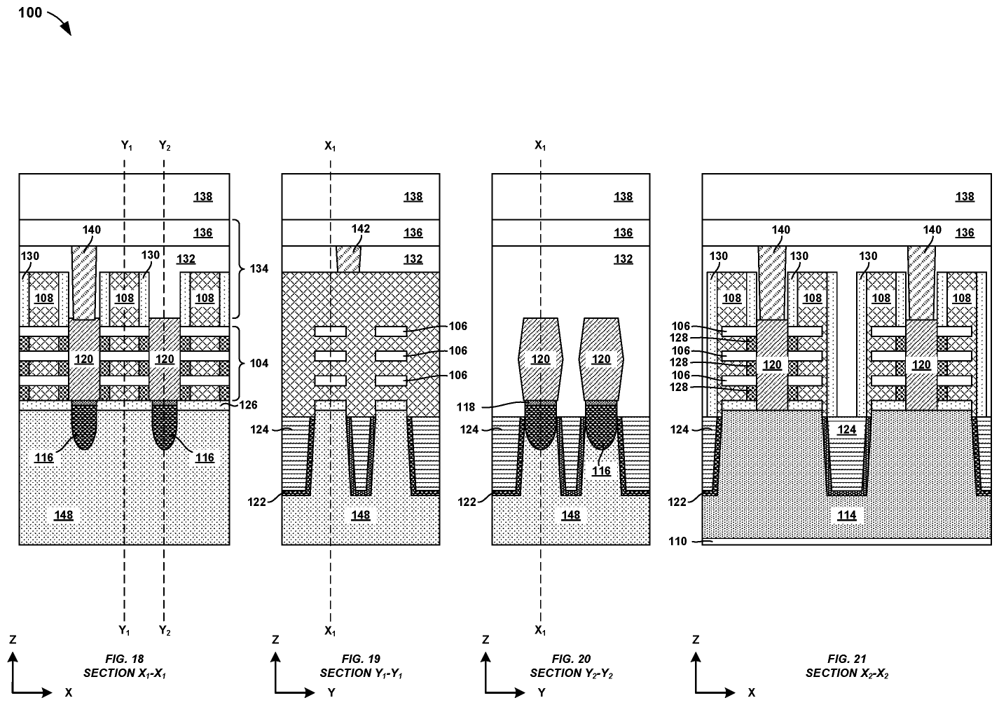

Referring now to FIGS. 18, 19, 20, and 21, the structure 100 is shown after forming a first backside dielectric layer 148 according to an embodiment of the invention. FIG. 18 depicts a cross-sectional view of the structure 100 taken along line X₁-X₁, FIG. 19 depicts a cross-sectional view of the structure 100 taken along line Y₁-Y₁, FIG. 20 depicts a cross-sectional view of the structure 100 taken along line Y₂-Y₂, and FIG. 21 depicts a cross-sectional view of the structure 100 taken along line X₂-X₂.

The first backside dielectric layer 148 is deposited according to known techniques. Specifically, a backside dielectric material is blanket deposited across the structure 100. The first backside dielectric layer 148 completely covers surfaces otherwise exposed by removing portions of the top semiconductor layer 114 in the previous operation. Specifically, the first backside dielectric layer 148 covers the placeholders 116, the stack spacers 126, the gates 108, and the STI regions in only the logic device regions, as illustrated. Meanwhile, the top semiconductor layer 114 and the etch stop layer 110 remain in the passive device regions. After deposition, known chemical mechanical polishing techniques may be used to remove excess portions of the backside dielectric material from bottom surfaces of the structure 100.

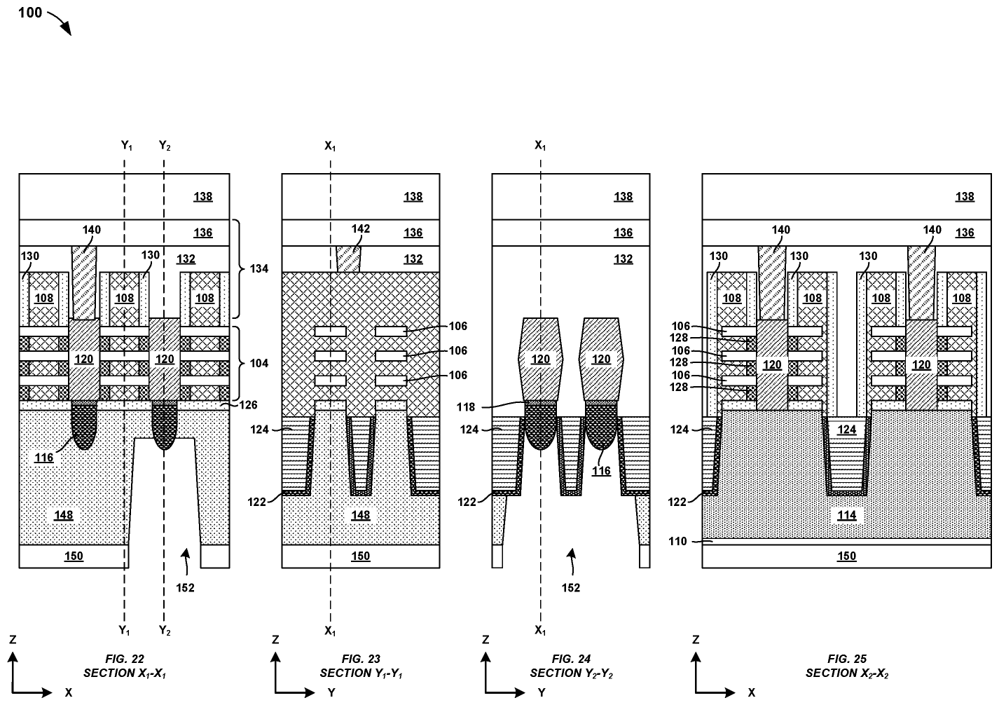

Referring now to FIGS. 22, 23, 24, and 25, the structure 100 is shown after forming a second mask 150 and removing portions of the first backside dielectric layer 148 to form backside contact trenches 152 according to an embodiment of the invention. FIG. 22 depicts a cross-sectional view of the structure 100 taken along line X₁-X₁, FIG. 23 depicts a cross-sectional view of the structure 100 taken along line Y₁-Y₁, FIG. 24 depicts a cross-sectional view of the structure 100 taken along line Y₂-Y₂, and FIG. 25 depicts a cross-sectional view of the structure 100 taken along line X₂-X₂.

First, the second mask 150 is deposited and subsequently patterned to expose certain portions of the structure 100 according to known techniques. The second mask 150 can be an organic planarization layer (OPL) or a layer of material that is capable of being planarized or etched by known techniques. In an embodiment, for example, the second mask 150 can be an amorphous carbon layer able to withstand subsequent processing temperatures. The second mask 150 can preferably have a thickness sufficient to cover existing structures. After depositing the second mask 150, a dry etching technique is applied to pattern or recess the second mask 150 according to known techniques. The second mask 150 is patterned consistent with a size and a location of subsequently formed backside contact structures. For example, after patterning the second mask 150, portions of the structure 100 in contact regions are exposed, as illustrated. Further, according to embodiments of the present disclosure, those contact regions are generally present in logic device regions (FIGS. 22, 23, and 24) and not present in passive device regions (FIG. 25). Specific to the embodiments disclosed herein, the second mask 150 is patterned selective to the first backside dielectric layer 148.

Exposed portions of the first backside dielectric layer 148 are then selectively removed to form the backside contact trenches 152 according to known techniques. Specifically, exposed portions of the first backside dielectric layer 148 are removed using known etching techniques suitable to remove silicon-based dielectric materials selective to the second mask 150, the placeholders 116, and the STI regions, as illustrated. In an embodiment, the exposed portions of the first backside dielectric layer 148 are removed using an anisotropic etch such as, for example, reactive ion etching (RIE). After removing the exposed portions of the first backside dielectric layer 148, portions of the placeholders 116 and the STI regions are exposed within the backside contact trenches 152, as illustrated. Significant to the embodiments disclosed herein, etching must continue until at least a portion of the placeholders 116 are exposed, for example, as best illustrated in FIG. 22. In such cases, some or all of the first backside dielectric layer 148 is completely removed from between adjacent STI regions, as best illustrated in FIG. 23.

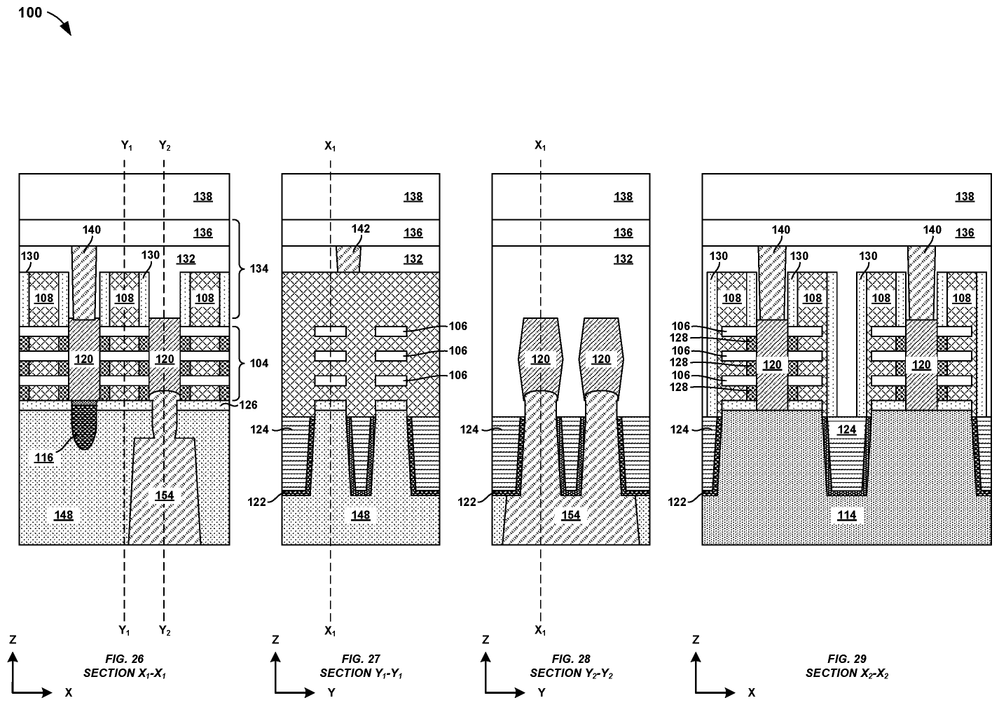

Referring now to FIGS. 26, 27, 28, and 29, the structure 100 is shown after removing the placeholders 116 and forming backside contact structures 154 according to an embodiment of the invention. FIG. 26 depicts a cross-sectional view of the structure 100 taken along line X₁-X₁, FIG. 27 depicts a cross-sectional view of the structure 100 taken along line Y₁-Y₁, FIG. 28 depicts a cross-sectional view of the structure 100 taken along line Y₂-Y₂, and FIG. 29 depicts a cross-sectional view of the structure 100 taken along line X₂-X₂.

The placeholders 116 exposed within the backside contact trenches 152 are selectively removed according to known techniques. Specifically, the placeholders 116 are etched or removed selective to the first backside dielectric layer 148, the stack spacers 126, the STI regions, and the buffer layer 118. The placeholders 116 can be removed using compatible selective dry etching techniques.

In doing so, the backside contact trenches 152 are enlarged or recessed directly beneath the source drain regions 120 without exposing the source drain regions 120 due to the existence of the buffer layers 118. Finally, exposed buffer layers 118 are subsequently removed selective to the surrounding structures according to known techniques. In some cases, some gouging or recessing of the source drain regions 120 may occur, as illustrated.

Next, the backside contact trenches 152 are filled with a conductive material to form the backside contact structures 154 according to known techniques. The backside contact structures 154 may include any suitable conductive material, such as, for example, copper, ruthenium, aluminum, tungsten, cobalt, or alloys thereof. In some embodiments, a metal silicide is formed at the bottom of the backside contact trenches prior to filling them with the conductive material.

After deposition, excess conductive material can be polished using known techniques until bottommost surfaces of the backside contact structures 154 are flush, or substantially flush, with bottommost surfaces of the first backside dielectric layer 148, as illustrated. After polishing, bottommost surfaces of the backside contact structures 154 are substantially flat. It is noted, the backside contact structures 154 may include, for example, backside source drain contacts, as illustrated, as well as backside gate contacts (not shown).

Specific to the disclosed embodiments, a merged backside contact structure (154) is formed across the N2P space effectively forming an electrical connection between the source drain region 120 associated with a pFET device and the source drain regions associated with an nFET device, as illustrated in FIG. 28.

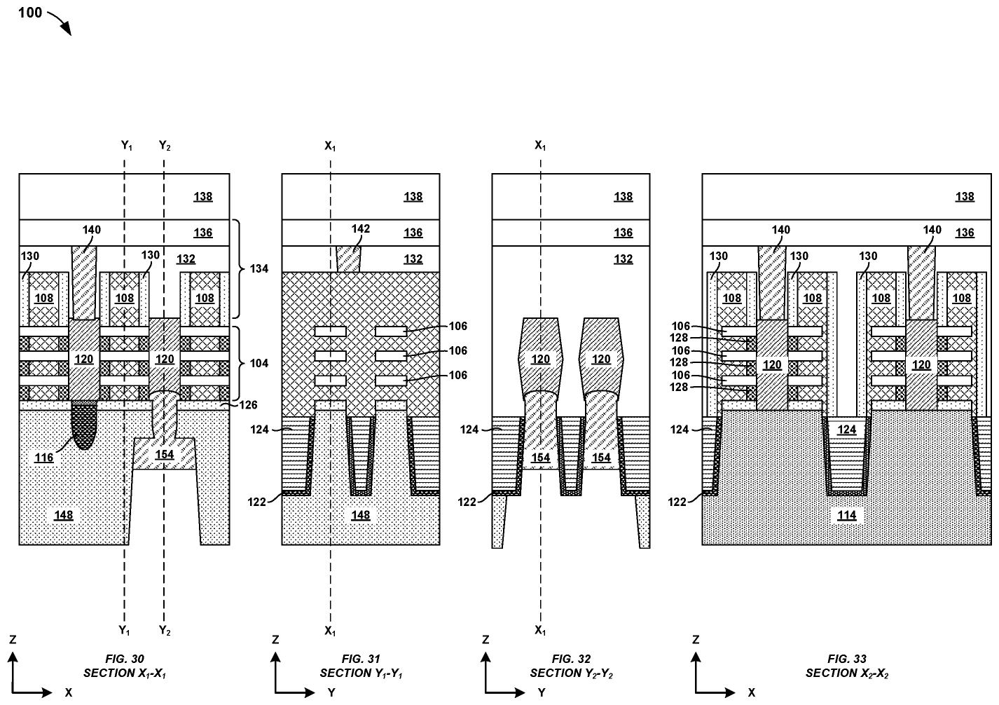

Referring now to FIGS. 30, 31, 32, and 33, the structure 100 is shown after recessing the backside contact structures 154 according to an embodiment of the invention. FIG. 30 depicts a cross-sectional view of the structure 100 taken along line X₁-X₁, FIG. 31 depicts a cross-sectional view of the structure 100 taken along line Y₁-Y₁, FIG. 32 depicts a cross-sectional view of the structure 100 taken along line Y₂-Y₂, and FIG. 33 depicts a cross-sectional view of the structure 100 taken along line X₂-X₂.

After filling the backside contact trenches 152, the conductive material is recessed according to known techniques. Specifically, the conductive material of the backside contact structures 154 is recessed selective to the first backside dielectric layer 148 using suitable techniques, such as, for example, reactive ion etching (RIE). In all cases, recessing is intended to expose the STI regions and un-merge the merged contact, as described below.

Critical to the disclosed embodiment, recessing the conductive material of the backside contact structures 154 effectively divides or splits the merged contact into two individual contacts, as illustrated. Doing so breaks or disrupts the electrical connection between the source drain region 120 associated with a pFET device and the source drain regions associated with an nFET device. After recessing the conductive material of the backside contact structures 154 the source drain region 120 associated with a pFET device is no longer electrically connected to the source drain regions associated with an nFET device.

In alternative structures, merged backside contact structures are often simply polished until the STI regions are exposed and two individual contact structures emerge. However, the bulk silicon substrate in the passive device regions is similarly polished down until the STI regions are exposed thereby eliminating the continuity of the silicon substrate beneath and below devices in the passive regions of the structure. Embodiments disclosed herein provide a novel solution for unmerging the backside contact structures while also maintaining the continuity of the silicon substrate beneath and below devices in the passive regions of the structure.

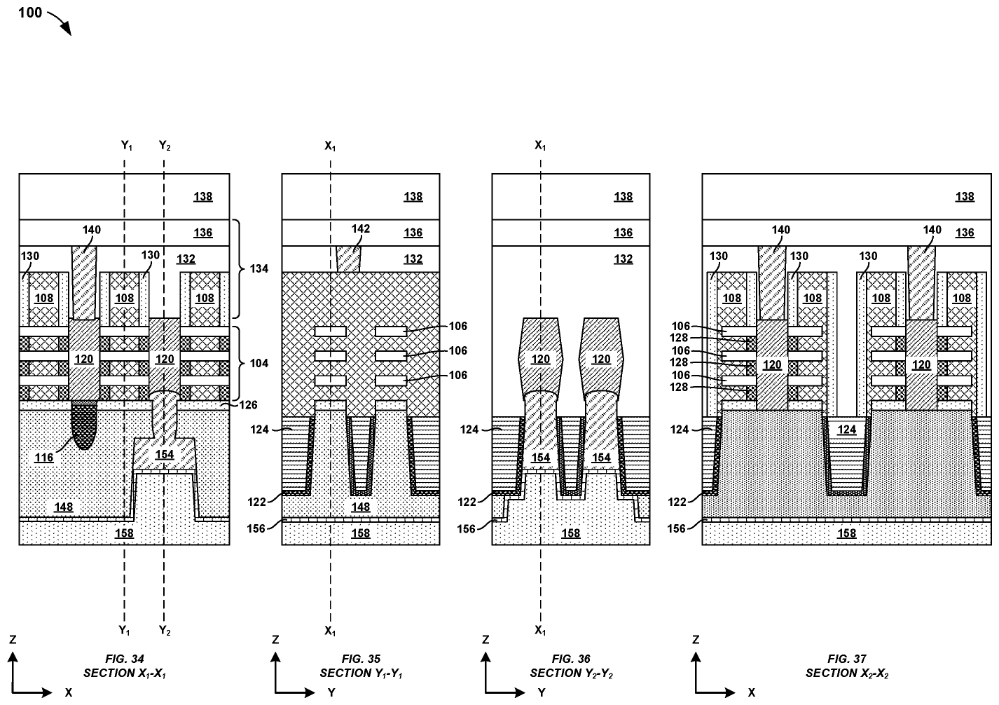

Referring now to FIGS. 34, 35, 36, and 37, the structure 100 is shown after forming a dielectric etch stop liner 156 and a second backside dielectric layer 158 according to an embodiment of the invention. FIG. 34 depicts a cross-sectional view of the structure 100 taken along line X₁-X₁, FIG. 35 depicts a cross-sectional view of the structure 100 taken along line Y₁-Y₁, FIG. 36 depicts a cross-sectional view of the structure 100 taken along line Y₂-Y₂, and FIG. 37 depicts a cross-sectional view of the structure 100 taken along line X₂-X₂.

First, the dielectric etch stop liner 156 is formed across the backside of the structure 100 according to known techniques. Specifically, a dielectric liner material is conformally deposited across exposed surfaces on the backside of the structure 100 including directly on the first backside dielectric layer 148, the STI regions, and the recessed surfaces of the backside contact structures 154, as illustrated. In some embodiments, for example, the dielectric etch stop liner 156 may be composed of low-k materials, such as, for example, aluminum nitride, aluminum oxide, NBLoK™ or other combinations thereof. According to embodiments of the present invention, the dielectric etch stop liner 156 provides added etch selectivity during backside processing. More specifically, the dielectric etch stop liner 156 is made from a material which may be removed selective to the surrounding materials, as described below.

Next, the second backside dielectric layer 158 is deposited according to known techniques. Specifically, a backside dielectric material is blanket deposited across the structure 100. The second backside dielectric layer 158 completely covers the dielectric etch stop liner 156, as illustrated. According to an embodiment, both the first backside dielectric layer 148 and the second backside dielectric layer 158 are made from the same or similar dielectric materials. In another embodiment, the first backside dielectric layer 148 and the second backside dielectric layer 158 are made from different dielectric materials. After deposition, known chemical mechanical polishing techniques may be used to remove excess portions of the backside dielectric material from bottom surfaces of the structure 100.

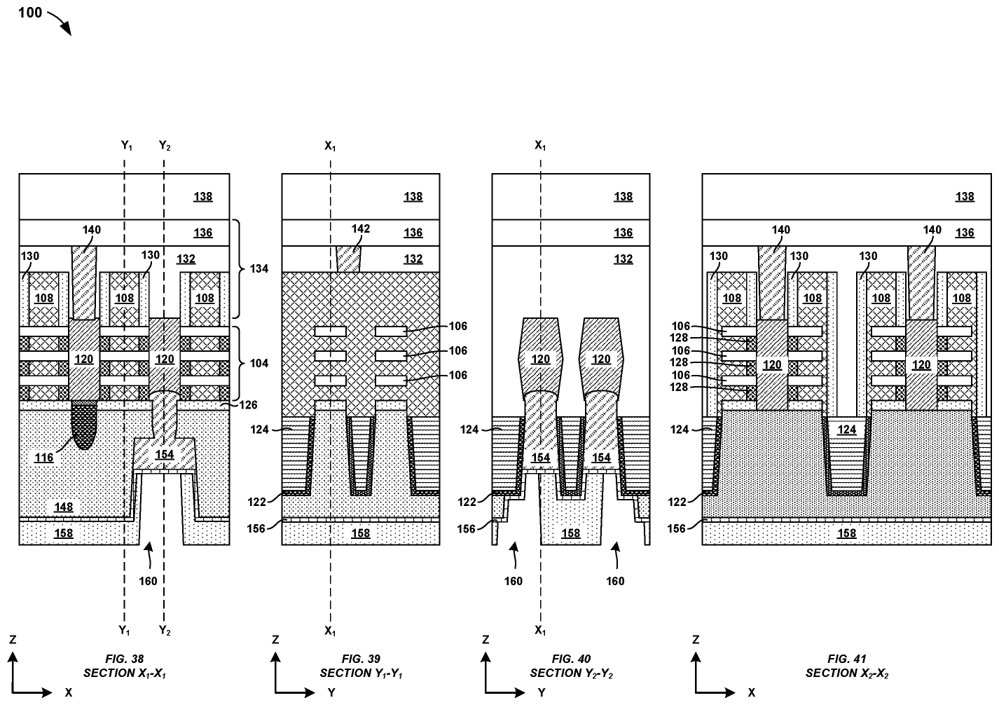

Referring now to FIGS. 38, 39, 40, and 41, the structure 100 is shown after removing portions of the second backside dielectric layer 158 to form backside via trenches 160 according to an embodiment of the invention. FIG. 38 depicts a cross-sectional view of the structure 100 taken along line X₁-X₁, FIG. 39 depicts a cross-sectional view of the structure 100 taken along line Y₁-Y₁, FIG. 40 depicts a cross-sectional view of the structure 100 taken along line Y₂-Y₂, and FIG. 41 depicts a cross-sectional view of the structure 100 taken along line X₂-X₂.

First, a mask (not shown) is deposited and subsequently patterned to expose certain portions of the structure 100 according to known techniques. Like above, the mask can be an organic planarization layer (OPL) or a layer of material that is capable of being planarized or etched by known techniques. After depositing the mask, a dry etching technique is applied to pattern or recess the mask according to known techniques. The mask is patterned consistent with a size and a location of subsequently formed backside via structures. For example, after patterning the mask, portions of the backside contact structures 154 are exposed, as illustrated. Specific to the embodiments disclosed herein, the second mask 150 is patterned selective to the second backside dielectric layer 158.

Exposed portions of the second backside dielectric layer 158 are then selectively removed to form the backside via trenches 160 according to known techniques. Specifically, exposed portions of the second backside dielectric layer 158 are removed using known etching techniques suitable to remove silicon-based dielectric materials selective to the mask and the dielectric etch stop liner 156, as illustrated. In an embodiment, the exposed portions of the second backside dielectric layer 158 are removed using an anisotropic etch such as, for example, reactive ion etching (RIE). After removing the exposed portions of the second backside dielectric layer 158, portions of the dielectric etch stop liner 156 are exposed within the backside contact trenches 152, as illustrated.

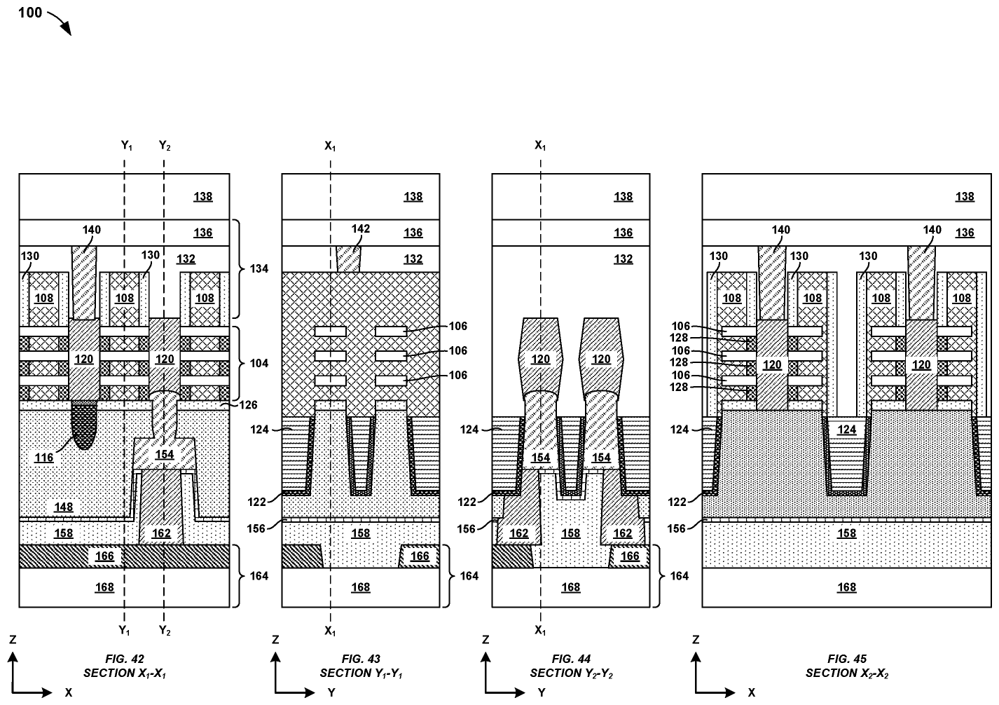

Referring now to FIGS. 42, 43, 44, and 45, the structure 100 is shown after forming backside via structures 162 and backside wiring layers 164 according to an embodiment of the invention. FIG. 42 depicts a cross-sectional view of the structure 100 taken along line X₁-X₁, FIG. 43 depicts a cross-sectional view of the structure 100 taken along line Y₁-Y₁, FIG. 44 depicts a cross-sectional view of the structure 100 taken along line Y₂-Y₂, and FIG. 45 depicts a cross-sectional view of the structure 100 taken along line X₂-X₂.

First, portions of the dielectric etch stop liner 156 exposed at the bottom of the backside via trenches 160 are selectively removed according to known techniques. Specifically, the exposed portions of the dielectric etch stop liner 156 are removed selective to the second backside dielectric layer 158 and the backside contact structures 154, as illustrated.

Next, the backside via trenches 160 are filled with a conductive material to form the backside via structures 162 according to known techniques. The backside via structures 162 may include any suitable conductive material, such as, for example, copper, ruthenium, aluminum, tungsten, cobalt, or alloys thereof.

After deposition, excess conductive material can be polished using known techniques until bottommost surfaces of the backside via structures 162 are flush, or substantially flush, with bottommost surfaces of the second backside dielectric layer 158, as illustrated. After polishing, bottommost surfaces of the backside via structures 162 are substantially flat.

Finally, after forming the backside via structures 162, the backside wiring layers 164 are subsequently formed according to known techniques. The backside wiring layers 164 typically include at least backside power rails 166 and a backside power delivery network 168.

According to the embodiment illustrated in FIGS. 42-45, the nanosheet transistor structures represented by the structure 100 have some distinctive and notable features. For instance, the structure 100 includes individual backside source drain contacts for logic devices (FIGS. 42-44) while maintaining silicon substrate continuity beneath and below passive devices (FIG. 45). Additionally, the disclosed embodiments provide a unique solution for forming individual, otherwise un-merged, backside contact structures (154) and backside via structures (162) in tight N2P space configurations. Specifically, for example, despite the tight N2P spacing represented in FIG. 44, sufficient spacing is provided between the backside via structures 162. Moreover, a size, for example width of the backside via structures 162, and the spacing between the backside via structures 162 can be tuned or tailored to meet design specifications without concerns of forming shorts.

With continued reference to FIGS. 42-45, and according to an embodiment, the structure 100 includes a logic device region including logic devices having backside contact structures embedded in a backside dielectric layer, and a passive device region including passive devices on a continuous silicon substrate, where a height of the backside dielectric layer in the logic device region is substantially equal to a height of the continuous silicon substrate in the passive device region.

With continued reference to FIGS. 42-45, and according to an embodiment, the structure 100 further includes a dielectric etch stop layer physically separating the backside dielectric layer from another backside dielectric layer.

With continued reference to FIGS. 42-45, and according to an embodiment, the structure 100 further includes a dielectric etch stop layer in direct contact with the backside contact structures and a shallow trench isolation region located at the N2P space.

With continued reference to FIGS. 42-45, and according to an embodiment, the structure 100 further includes backside via structures in direct contact with the backside contact structures, where portions of the backside via structures also directly contact adjacent shallow trench isolation regions.

With continued reference to FIGS. 42-45, and according to an embodiment, the structure 100 further includes a placeholder directly beneath a source drain region.

With continued reference to FIGS. 42-45, and according to an embodiment, the bottommost surfaces of the backside contact structures are above bottommost surfaces of adjacent shallow trench isolation regions.

With continued reference to FIGS. 42-45, and according to an embodiment, the backside contact structure is self-aligned to adjacent shallow trench isolation regions.

With continued reference to FIGS. 42-45, and according to an embodiment, the structure 100 includes a logic device region including logic devices having backside contact structures embedded in a first backside dielectric layer, a passive device region including passive devices on a continuous silicon substrate, and a second backside dielectric layer below the first backside dielectric layer in the logic device region and below the continuous silicon substrate in the passive device region, where a topmost surface of the second backside dielectric layer is above a bottommost surface of the first backside dielectric layer.

With continued reference to FIGS. 42-45, and according to an embodiment, the structure 100 includes a logic device region including logic devices having backside contact structures embedded in a first backside dielectric layer, a passive device region including passive devices on a continuous silicon substrate, and a dielectric etch stop layer physically separating the first backside dielectric layer from a second backside dielectric layer.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A nanosheet semiconductor structure comprising:
a logic device region comprising logic devices having backside contact structures embedded in a backside dielectric layer; and
a passive device region comprising passive devices on a continuous silicon substrate,
wherein a height of the backside dielectric layer in the logic device region is substantially equal to a height of the continuous silicon substrate in the passive device region.

2. The semiconductor structure according to claim 1, further comprising:
a dielectric etch stop layer physically separating the backside dielectric layer from another backside dielectric layer.

3. The semiconductor structure according to claim 1, further comprising:
a dielectric etch stop layer in direct contact with the backside contact structures and a shallow trench isolation region located at the N2P space.

4. The semiconductor structure according to claim 1, further comprising:
backside via structures in direct contact with the backside contact structures, wherein portions of the backside via structures also directly contact adjacent shallow trench isolation regions.

5. The semiconductor structure according to claim 1, further comprising:
a placeholder directly beneath a source drain region.

6. The semiconductor structure according to claim 1, wherein bottommost surfaces of the backside contact structures are above bottommost surfaces of adjacent shallow trench isolation regions.

7. The semiconductor structure according to claim 1, wherein the backside contact structure is self-aligned to adjacent shallow trench isolation regions.

8. A nanosheet semiconductor structure comprising:
a logic device region comprising logic devices having backside contact structures embedded in a first backside dielectric layer;
a passive device region comprising passive devices on a continuous silicon substrate; and
a second backside dielectric layer below the first backside dielectric layer in the logic device region and below the continuous silicon substrate in the passive device region, wherein a topmost surface of the second backside dielectric layer is above a bottommost surface of the first backside dielectric layer.

9. The semiconductor structure according to claim 8, further comprising:
a dielectric etch stop layer physically separating the first backside dielectric layer from the second backside dielectric layer.

10. The semiconductor structure according to claim 8, further comprising:
a dielectric etch stop layer in direct contact with the backside contact structures and a shallow trench isolation region located at the N2P space.

11. The semiconductor structure according to claim 8, further comprising:
backside via structures in direct contact with the backside contact structures, wherein portions of the backside via structures also directly contact adjacent shallow trench isolation regions.

12. The semiconductor structure according to claim 8, further comprising:
a placeholder directly beneath a source drain region.

13. The semiconductor structure according to claim 8, wherein bottommost surfaces of the backside contact structures are above bottommost surfaces of adjacent shallow trench isolation regions.

14. The semiconductor structure according to claim 8, wherein the backside contact structure is self-aligned to adjacent shallow trench isolation regions.

15. A nanosheet semiconductor structure comprising:
a logic device region comprising logic devices having backside contact structures embedded in a first backside dielectric layer;
a passive device region comprising passive devices on a continuous silicon substrate; and
a dielectric etch stop layer physically separating the first backside dielectric layer from a second backside dielectric layer.

16. The semiconductor structure according to claim 15, further comprising:
a dielectric etch stop layer in direct contact with the backside contact structures and a shallow trench isolation region located at the N2P space.

17. The semiconductor structure according to claim 15, further comprising:
backside via structures in direct contact with the backside contact structures, wherein portions of the backside via structures also directly contact adjacent shallow trench isolation regions.

18. The semiconductor structure according to claim 15, further comprising:
a placeholder directly beneath a source drain region.

19. The semiconductor structure according to claim 15, wherein bottommost surfaces of the backside contact structures are above bottommost surfaces of adjacent shallow trench isolation regions.

20. The semiconductor structure according to claim 15, wherein the backside contact structure is self-aligned to adjacent shallow trench isolation regions.
